(19) United States
(12) Patent Application Publication
(10) Pub. No.: US 2016/0027618 A1
(43) Pub. Date: Jan. 28, 2016

(54) PLASMA PROCESSING APPARATUS AND PLASMA PROCESSING METHOD

(71) Applicant: Hitachi High-Technologies Corporation, Tokyo (JP)

(72) Inventors: Masatoshi Kawakami, Tokyo (JP); Hiroho Kitada, Tokyo (JP); Hideki Kihara, Tokyo (JP); Hironori Kusumoto, Tokyo (JP); Masahiro Sumiya, Tokyo (JP); Motohiro Tanaka, Tokyo (JP); Yutaka Kozuma, Tokyo (JP)

(73) Assignee: HITACHI HIGH-TECHNOLOGIES CORPORATION

(21) Appl. No.: 14/626,988

(22) Filed: Feb. 20, 2015

(30) Foreign Application Priority Data
Jul. 24, 2014 (JP) 2014-150324

(51) Int. Cl. H01J 37/32; H01L 21/3213; H01L 21/311; H01L 21/67; H01L 21/3065

(52) U.S. Cl. CPC H01J 37/32449; H01J 37/3244; H01J 37/32009; H01L 21/67069; H01L 21/3065; H01L 21/31116; H01L 21/31138; H01L 21/32136

(57) ABSTRACT

A plasma processing apparatus includes a sample stage in a processing chamber in a vacuum container having a placement surface on which a wafer to be processed by using the plasma is placed, a discharge pump connected to a discharge port disposed below the sample stage, and an adjuster that adjusts the amount of discharged gas, in which a first process step of supplying a first processing gas from above the placement surface into the processing chamber and supplying a second processing gas from below the placement surface into the processing chamber to process the wafer by using the first processing gas and a second process step where the first processing gas and the second processing gas are reversed are repeatedly switched over therebetween, and the adjuster adjusts a pressure in the processing chamber to a predetermined value during the processing.

### BACKGROUND OF THE INVENTION

The present invention relates to a plasma processing apparatus and a plasma processing method for processing a substrate-shaped sample, such as a semiconductor wafer, placed in a processing chamber in a vacuum container by using plasma formed in the processing chamber, and particularly to a plasma processing apparatus and a plasma processing method for performing the processing by introducing a plurality of processing gases into the processing chamber.

A semiconductor device in recent years has increasingly been downsized, and precision in an etching process has been changing from nanometer level to angstrom level in order to achieve such a downsized circuit. To perform etching with such high precision, it is an important challenge to achieve the characteristics and conditions of the process with precision.

In general, in plasma process steps, to improve the controllability of the process, it is necessary to achieve the flow rate and composition of a processing gas used in the process in a short period with precision. To achieve the object, there is known related art as described in JP-A-2008-91651, in which a gas line through which a processing gas to be supplied to a processing chamber is supplied, being connected to and branched from the gas supply line and discharges the processing gas to a discharge pump for the processing chamber are provided, and the passage of the processing gas to the gas lines is switched with the aid of valve operation to control the supply of the processing gas to the processing chamber.

Further, as disclosed in JP-A-2008-41723, in a process of repeatedly performing an etching step and a deposition step in a short period, there is a known technology for introducing an adjustment gas in the deposition step through an adjustment gas line connected to a discharge line between a discharge pump and a processing chamber to supply the adjustment gas into the reaction chamber for prevention of a decrease in the pressure in the reaction chamber at the start of the deposition step. In this example, since it is difficult to operate a pressure adjustment valve on the discharge line in accordance with the timing of switching the processing gases to achieve a value of the pressure suitable for the process, the adjustment gas is introduced into the reaction chamber in accordance with the timing described above. In this related art, the adjustment gas is supplied through the lower end of the reaction chamber to prevent the pressure in the reaction chamber from changing even when the composition of the processing gases changes during the process.

### SUMMARY OF THE INVENTION

The related arts described above are problematic because the following points are not adequately considered.

That is, according to JP-A-2008-91651 described above, in the case that the flow rate and composition of the processing gas is switched or changed in a short period, it attempts to solve the problem that the pressure adjustment means of related art disposed on the discharge path extending from the processing chamber has too low responsivity to follow the switching or change, by temporarily increasing the flow rate of the gas. In this related art, however, the flow rate of the gas needs to be increased whenever the gas is switched, and a waiting period is therefore required and does not allow the processing conditions to be changed in a short period Further, the change in the flow rate of the gas in the processing chamber inevitably affects characteristics of the etching performed in the processing chamber, so that there was a concern that an intended process result may not be obtained.

Further, JP-A-2008-41723 relates to a situation, in the case that the composition, the flow rate, and other processing conditions of the processing gas is repeatedly switched in a short period, the pressure adjustment gas is introduced through the lower end of the reaction chamber in order to reduce the amount of change in the pressure in the reaction chamber. In this related art, however, since the adjustment gas is introduced through the discharge line via a discharge port, it is impossible or difficult to adjust the flow rate of discharged gas during the introduction of the adjustment gas. As a result, variation in the pressure in the processing chamber due to reaction products produced from a wafer and the sidewall of a vacuum device during the process cannot be adjusted, which means that the intended effect of preventing any change in the pressure in the reaction chamber due to a change in the processing gas conditions cannot be achieved.

For these reasons, the related arts described above could not achieve required processing conditions with precision, resulting in a decrease in yield in the process. The problems were not sufficiently considered in the related arts described above.

An object of the present invention is to provide a plasma processing apparatus and a plasma processing method allowing improvement in yield in the process.

The object described above is achieved by a plasma processing apparatus comprising: a vacuum container; a processing chamber that is disposed in the vacuum container and that has an inner space in which plasma is formed; a sample stage that is disposed in the processing chamber and that has a placement surface on which a wafer to be processed by using the plasma is placed; a discharge port disposed below the sample stage in the processing chamber; a discharge pump disposed such that the discharge pump is connected to the discharge port; and an adjuster that adjusts an amount of gas discharged through the discharge port, wherein, a first process step of supplying a first processing gas from above the placement surface into the processing chamber and supplying a second processing gas from below the placement surface into the processing chamber to process the wafer by using the first processing gas and a second process step of supplying the second processing gas from above the placement surface into the processing chamber and supplying the first processing gas from below the placement surface into the processing chamber to process the wafer by using the second processing gas are repeatedly switched over therebetween to process the wafer, and the adjuster adjusts a pressure in the processing chamber during the processing of the wafer to a predetermined value.

The object described above is also achieved by a plasma processing method comprising the steps of: placing a wafer to be processed on a placement surface of a sample stage disposed in a processing chamber in a vacuum container; forming plasma in the processing chamber; repeatedly switching over between a first process step of supplying a first processing gas from above the placement surface into the processing chamber and supplying a second processing gas from below the placement surface into the processing chamber to process the wafer by using the first processing gas and a second process step of supplying the second processing gas from above the placement surface into the processing chamber and supplying the first processing gas from below the placement surface into the processing chamber to process the wafer by using the second processing gas to process the wafer; and adjusting an amount of gas discharged through a discharge port disposed below the sample stage in the processing chamber during the processing of the wafer to adjust a pressure in the processing chamber to a predetermined value.

The present invention provides an advantageous effect of solving the problem in which pressure control in the processing chamber is not responsive enough and capable of finer etching control by achieving high-speed gas switching.

Other objects, features and advantages of the invention will become apparent from the following description of the embodiments of the invention taken in conjunction with the accompanying drawings.

### BRIEF DESCRIPTION OF THE DRAWINGS

FIG. 1 is a longitudinal sectional view schematically showing the configuration of a plasma processing apparatus according to an embodiment of the present invention;

FIG. 2 schematically shows a state in which the plasma processing apparatus according to the embodiment shown in FIG. 1 supplies a processing chamber with a process gas a and a process gas b via a shower plate;

FIG. 3 is a longitudinal sectional view schematically showing a state in which the plasma processing apparatus according to the embodiment shown in FIG. 1 supplies the processing chamber with the process gas a through the shower plate and the process gas b through an opening below a wafer placement electrode;

FIG. 4 shows a method for supplying a processing chamber 4 with the process gas a without using a shower plate 2 and the process gas b through the shower plate 2;

FIG. 5 is a longitudinal sectional view schematically showing a state in which a reaction product is formed in the plasma processing apparatus according to the embodiment shown in FIG. 1 during a process carried out by supplying process gases different from each other through first and second gas supply paths; and

FIG. 6 is a longitudinal sectional view schematically showing a state in which a reaction product is formed in the plasma processing apparatus according to the embodiment shown in FIG. 1 during a process carried out by supplying process gases different from each other through the first and second gas supply paths.

### DETAILED DESCRIPTION OF THE EMBODIMENTS

Embodiments of the present invention will be described below with reference to the drawings.

[First Embodiment]

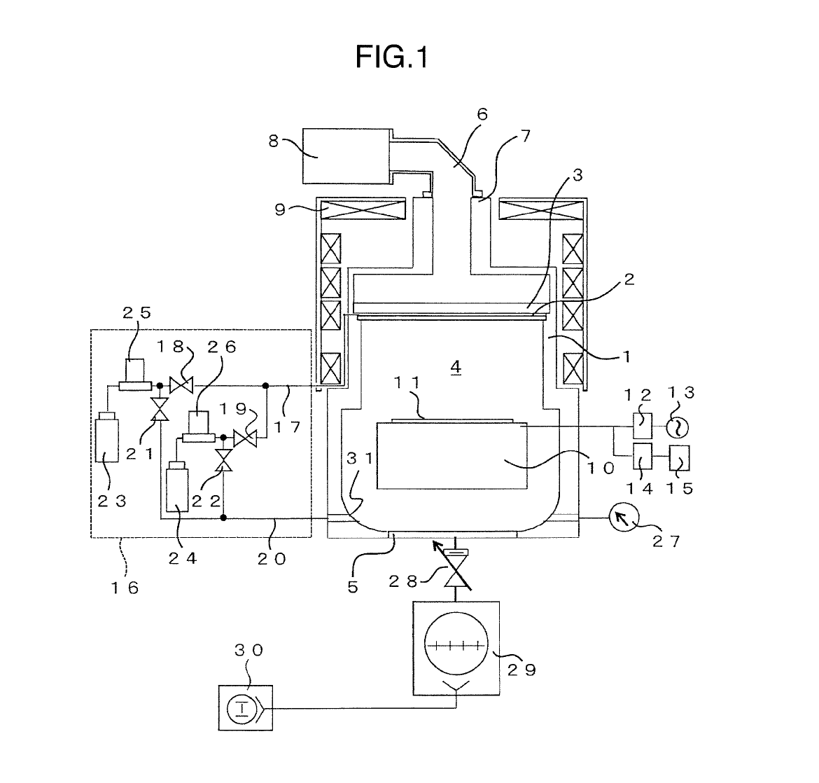

An embodiment of the present invention will be described below with reference to FIG. 1. FIG. 1 shows a plasma processing apparatus according to the embodiment of the present invention. In the present embodiment, the description will be particularly made of a plasma processing apparatus that uses a microwave electric field as an electric field supplied into a processing chamber for plasma formation and induces electron cyclotron resonance (ECR) based on interaction between a magnetic field supplied from a solenoid coil and the microwave electric field to excite particles of a processing gas to form plasma that etches a sample, such as a wafer.

FIG. 1 is a longitudinal sectional view schematically showing the configuration of the plasma processing apparatus according to the embodiment of the present invention In FIG. 1, the plasma processing apparatus according to the embodiment of the present invention includes a vacuum container 1, which has a cylindrical shape or a shape considered to be an approximately cylindrical shape with an upper portion of the sidewall of the cylindrical shape open, and a disk-shaped dielectric window 3 (for example, made of quartz), which is placed on the upper portion of the vacuum container 1, and the vacuum container 1 and the dielectric window 3 are bonded to each other to achieve hermetically sealed interior.

Further, a disk-shaped shower plate 2 is disposed below the dielectric window 3. The shower plate 2 is made of a dielectric material (for example, quartz or yttria) and has a plurality of through holes through which an etching gas is introduced into a processing chamber 4 in the vacuum container 1. The interior of the processing chamber 4 is hermetically sealed from the outside with the sidewall of the vacuum container 1 and the dielectric window 3 above the processing chamber 4 intimately in contact with each other. Further, the ceiling surface of the processing chamber 4 is formed of the shower plate 2, which faces plasma formed in the processing chamber 4, and heat from the plasma is transferred during the etching process through the shower plate 2 to the dielectric window 3 disposed thereabove.

A space sandwiched by the shower plate 2 and the dielectric window 3 from above and below is created, and the interior of the space communicates with a gas supplier 16, which causes the etching gas to flow. After the etching gas supplied from the gas supplier 16 is diffused in the space, the etching gas passes through the through holes in the shower plate 2 and is introduced into the processing chamber 4. A variable conductance valve 28, a turbo molecular pump 29, and a dry pump 30 which is a pump for rough pumping, are disposed below the vacuum container 1 and communicate with the processing chamber 4 via a circular vacuum discharge port 5, which is the bottom surface of the processing chamber 4 in the vacuum container 1 and disposed directly below a wafer placement electrode 10.

To transfer an electric field for plasma generation to the processing chamber 4, a waveguide tube 6 (or antenna), which is means for allowing the electric field to propagate and introducing the electric field through the dielectric window 3 into the processing chamber 4, is disposed above the dielectric window 3. The waveguide tube 6 has a cylindrical tube-shaped portion extending in the vertical direction. An upper end portion of the tube-shaped portion is connected to one end of a tube-shaped portion having a rectangular cross-sectional shape and extending in the horizontal direction, and the cylindrical tube-shaped portion beyond the connected portion is directed in the horizontal direction. Further, a magnetron 8, which is an electric field generating power supply for exciting and forming an electric field to be transferred through the waveguide tube 6, is disposed at the other end of the tube-shaped portion having a rectangular cross-sectional shape. The frequency of the electric field is not limited to a specific value, and a 2.45-GHz microwave is used in the present embodiment.

Magnetic field generating coils 9, which forma magnetic field, are disposed around the outer circumferential portion of the processing chamber 4, specifically, above the dielectric window 3 and around the outer circumference of the sidewall of the cylindrical portion of the vacuum container 1. The electric field excited by the electromagnetic wave generating power supply 8 and introduced into the processing chamber 4 via the waveguide tube 6, a cavity resonator 7, the dielectric window 3, and the shower plate 2 interacts with the magnetic field formed by the magnetic field generating coils 9 to which DC current is supplied and supplied into the processing chamber 4, and the interaction excites particles of the etching gas to produce plasma in a space below the shower plate 2 in the processing chamber 4. Further, in the present embodiment, the wafer placement electrode 10, which is a sample stage having a circular upper surface on which a wafer 11 being a sample to be processed is placed and which faces the shower plate 2, is disposed below the shower plate 2 in a lower portion of the processing chamber 4.

In this plasma processing apparatus, the wafer 11, which is transported through a transportation chamber into the processing chamber 4, is placed on a film that is made of alumina, yttria, or any other dielectric material and forms a placement surface of the wafer placement electrode 10. The transportation chamber is not shown but is a vacuum transportation container which is connected to the sidewall of the vacuum container 1, in which the pressure is reduced, and in which a robot arm or any other transportation means is disposed Thereafter, electrostatic force formed by DC voltage applied to a metal, film-shaped electrode disposed in the dielectric film and electrically connected to a DC power supply 15 via a filter causes the wafer 11 to be sucked onto the upper surface of the dielectric film and held on the wafer placement electrode 10.

A predetermined etching processing gas is then supplied from the gas supplier 16 into the processing chamber 4, and the pressure in the processing chamber 4 is adjusted by the variable conductance valve 28 to a pressure suitable for the etching process based on a result measured with a pressure gauge 27. The electric field and the magnetic field are supplied into the processing chamber 4 and excite the particles of the processing gas. Plasma is thus formed in a space between the wafer placement electrode 10 and the shower plate 2 in the processing chamber 4. In the state in which the plasma is formed, high-frequency electric power is applied to the wafer placement electrode 10, which is a metal member having a circular or cylindrical shape and disposed in the sample stage, from a high-frequency power supply 13 via a matching circuit 12, and bias potential is formed above the wafer 11. Charged particles in the plasma are attracted onto the surface of the wafer 11, and a process target film disposed on the surface of the wafer 11 is etched.

When it is detected that the process target film has been processed, the application of the high-frequency electric power to the wafer placement electrode 10 is terminated, and the supply of the processing gas is also terminated. In this state, the processing chamber 4 and the transportation chamber are allowed to communicate with each other, and the robot arm or any other transportation means enters the processing chamber 4, takes the wafer 11 from the sample stage, and transports the wafer 11 out of the processing chamber 4 into the transportation chamber. When another unprocessed wafer 11 is present, the wafer is transported into the processing chamber 4 and placed on the sample stage.

A description will next be made of the gas supplier 16 which has a high-speed gas switching mechanism. The gas supplier 16 in this example includes a gas supply source a23 which stores and supplies a process gas a, and a gas supply source b24 which stores and supplies a process gas b. Further, the gas supplier 16 is connected to a first gas supply path 17 and a second gas supply path 20 which are connected to the vacuum container 1.

The first supply path 17 connects the gas supplier 16 and the vacuum container 1 to each other and communicates with a gap between the shower plate 2 and the dielectric window 3. The second supply path 20 connects the gas supplier 16 and the vacuum container 1 to each other and communicates with an opening 31, which is disposed below the placement surface of the wafer placement electrode 10 in the processing chamber 4. The second supply path 20 is a path through which a gas from a mass flow controller a25 flows into a space between the vacuum discharge port 5 and the wafer placement electrode 10 in the processing chamber 4 without passing through the shower plate 2.

The gas supplier 16 includes the mass flow controller a25, which communicates with the gas supply source a23 and adjusts the flow rate and speed of the process gas a. The gas supplier 16 further includes a gas path formed of the mass flow controller a25 and a pipe which is branched into the first supply path 17 and the second supply path, which are connected to each other and through which the process gas a flows. A first valve a18 and a second valve a21, which open and close channels or adjust the amount of gas passage, are disposed on the branched gas paths.

The gas supplier 16 further includes a mass flow controller b26 which communicates with the gas supply source b24 and adjusts the flow rate and speed of the process gas b, and a gas path formed of the mass flow controller b26 and a pipe which is branched into the first supply path 17 and the second supply path, which are connected to each other and through which the process gash flows. A first valve b18 and a second valve b21, which open and close channels or adjust the amount of gas passage, are disposed on the branched gas paths. That is, each of the first supply path 17 and the second supply path 20 is connected to the first gas supply source 23 and the second gas supply source 24, and the gas paths from the gas supply sources are merged together to allow the gases to flow into the processing chamber 4.

Although not shown in FIG. 1, in the plasma processing apparatus according to the present embodiment, a controller that is not shown controls the following operations: causing the magnetron 8 to start and stop generating an electric field and the magnetic field generating coil 9 to start and stop generating a magnetic field; causing the high-frequency power supply 13 to start and stop supplying the high-frequency electric power; adjusting the amount and speed of the process gas supplied from the gas supplier 16 and causing the gas supplier 16 to stop supplying the process gas; discharging gases from the processing chamber 4 through the vacuum discharge port 5 and adjusting the amount and speed of the discharged gases; causing the wafer placement electrode 10 to suck and release the wafer 11; transporting the wafer 11 into and out of the processing chamber 4; and other types of operation. The controller includes an interface with a communication means for signal communication with an external part or apparatus to be controlled, a RAM, a ROM, a CD-ROM, or a DVD-ROM, or other storage devices that store software in which an algorithm prepared in advance is written and data contained in a signal received through the interface, a CPU or any other generally known computing device that calculates an instruction signal and a control target value based on the data and the software stored in the storage devices, and a communication path that connects a signal between the components described above in a communicatable manner.

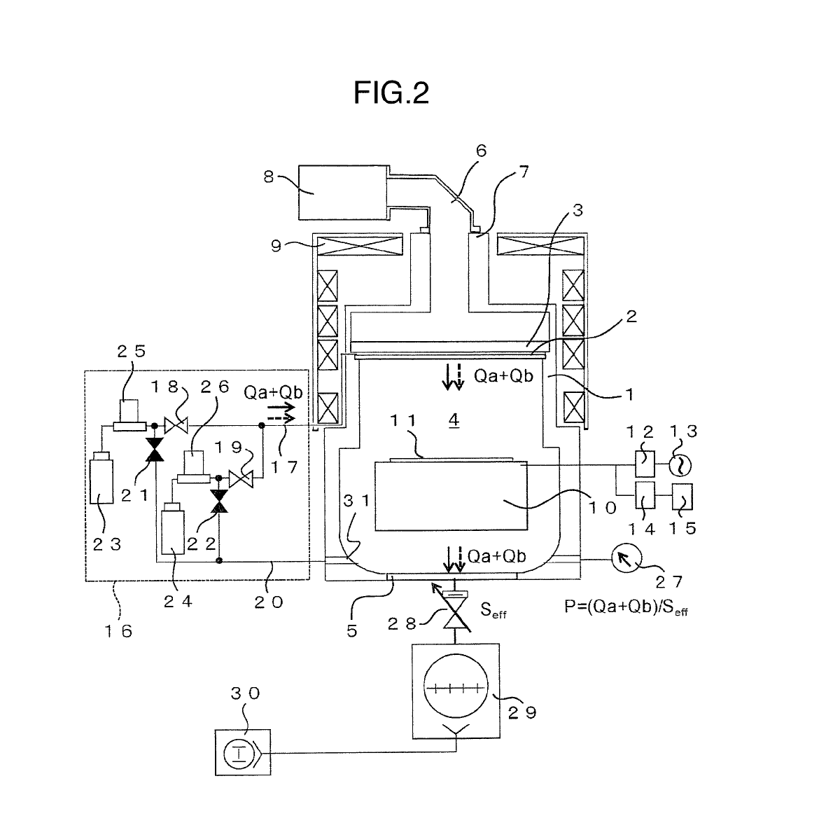

A description will next be made of the operation of the gas supplier 16. FIG. 2 schematically shows astute in which the plasma processing apparatus according to the embodiment shown in FIG. 1 supplies the processing chamber 4 with the process gas a and the process gas b via the shower plate 2.

After the first valve a18 is opened and the second valve a21 is closed in response to a signal from the controller, the process gas a from the gas supply source a23 flows through the first gas supply path 17 and is supplied into the processing chamber 4 toward the placement surface of the wafer placement electrode 10 from above via the plurality of through holes disposed in the shower plate 2. Let Qa be the flow rate of the process gas a.

Further, after the first valve b19 is opened and the second valve b22 is closed in response to a signal from the controller, the process gas b from the gas supply source b24 flows through the first gas supply path 17 and is supplied into the processing chamber 4 via the through holes in the shower plate 2. Let Qb be the flow rate of the process gas b.

In the example shown in FIG. 2, the process gas a and the process gas b are both supplied to the processing chamber 4 via the shower plate 2. The sum of the flow rates of the processing gases supplied to the processing chamber 4 is Qa+Qb. If no reaction product is formed in the processing chamber 4 during the processing of the wafer 11, the sum of the flow rates of the gases discharged from the processing chamber 4 through the vacuum discharge port 5 is also Oa+Qb.

During the supply of the process gases to the processing chamber 4 at the flow rate Qa+Qb, the controller activates the variable conductance valve 28 in such a way that the pressure in the processing chamber 4 to which the process gas a and the process gas b are supplied or the pressure measured with the pressure gauge 27 has a preset value P. An effective discharge speed Seff is thus adjusted. The variable conductance valve 28 is disposed in a position on a discharge line including a pipe that connects the vacuum discharge port 5 to the inlet of the turbo molecular pump 29 and includes a plurality of flaps which are not shown and each of which rotates around a shaft disposed in parallel to the transverse direction of the channel cross section of the pipe. When the flaps rotate, the channel cross-sectional area of the pipe variably increases or decreases. The controller receives a signal outputted from the pressure gauge 27 and issues an instruction signal based on a value derived from the output signal to adjust the flow rate or speed of the discharged gases by changing the angle of each of the flaps with respect to the channel cross section to increase or decrease the flow path cross-sectional area in such a way that the pressure in the processing chamber 4 has an intended value.

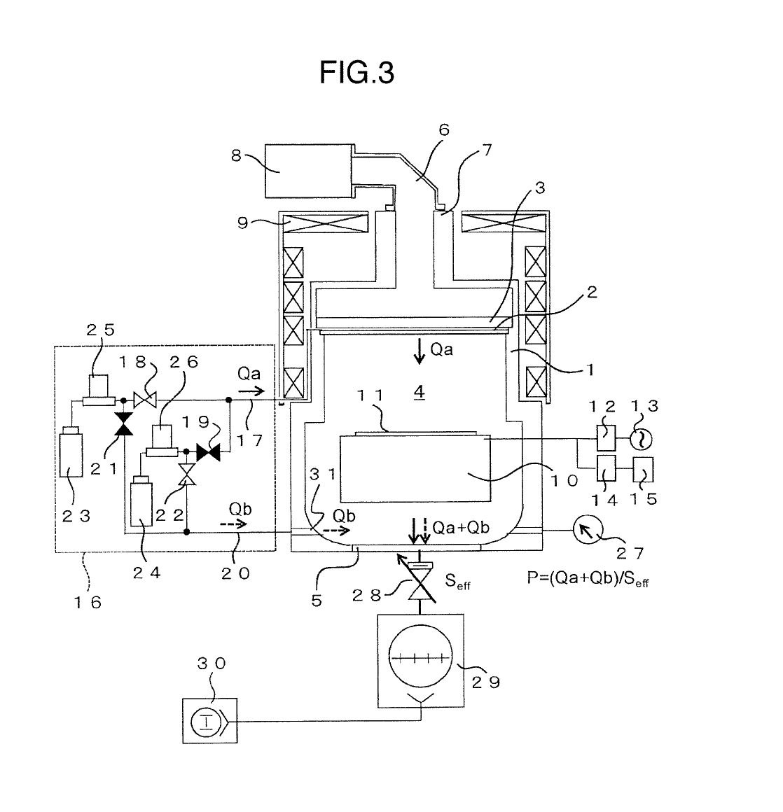

FIG. 3 schematically shows a state in which the plasma processing apparatus according to the embodiment shown in FIG. supplies the processing chamber 4 with the process gas a through the shower plate 2 and the process gas b through the opening below the wafer placement electrode 10. In the example shown in FIG. 3, a state in which the process gas a is supplied through the through holes in the shower plate 2 to the processing chamber 4, and the process gas b is supplied through the opening 31 to the processing chamber 4 is shown.

In this state, the controller issues an instruction signal to open the first valve a18 and close the second valve b21. As a result, the process gas a flows through the first gas supply path and is supplied to the processing chamber 4 through the through holes in the shower plate 2 On the other hand, after the first valve b19 is closed and the second valve b22 is opened, the process gas b flows through the second gas supply path 20 and is supplied to the processing chamber 4 through the opening 31 disposed below the wafer placement electrode 10.

In the example shown in FIG. 3, the flow rate of the process gas a and the flow rate of the process gas b supplied to the processing chamber 4 are Qa and Qb, respectively, as in the case shown in FIG. 2. Therefore, in the state shown in FIG. 3, the flow rate of the processing gases supplied into the processing chamber 4 is also Qa+Qb. The amount of gases and particles present in the processing chamber 4 and to be discharged through the vacuum discharge port 5 is therefore equal to the process gas flow rate Qa+Qb if the amount of substance produced in the processing chamber 4 is zero or negligible. Therefore, the effective discharge speed Seff achieved by the operation of the variable conductance valve 28 is equal to the value in the example shown in FIG. 2, and the pressure in the processing chamber 4 is also set at the same value P.

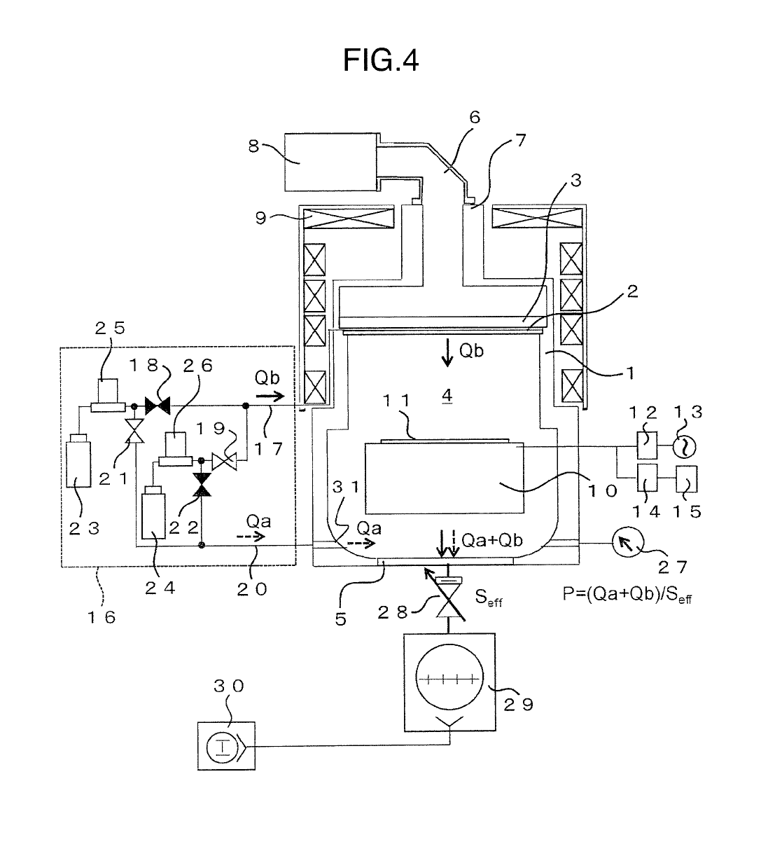

FIG. 4 schematically shows a state in which the plasma processing apparatus according to the embodiment shown in FIG. 1 supplies the processing chamber 4 with the process gas a and the process gas b through the shower plate 2. In the example shown in FIG. 4, the process gas b is supplied to the processing chamber 4 through the through holes in the shower plate 2, and the process gas a is supplied to the processing chamber 4 through the opening 31.

In the example shown in FIG. 4, the first valve a18 is closed and the second valve a21 is opened based on an instruction from the controller, and the process gas a flows through the second gas supply path 20 and is supplied at the flow rate Qa through the opening 31 to the space below the wafer placement electrode 10 in the processing chamber 4. On the other hand, the first valve b19 is opened and the second valve b22 is closed, and the process gas b flows through the first gas supply path 17 and is supplied at the flow rate Qb through the through holes in the shower plate 2 to an upper portion of the processing chamber 4.

Also in this state, since the flow rate of the particles of the gases discharged through the vacuum discharge port 5 disposed at the bottom surface of the processing chamber 4 is Qa+Qb assuming that the amount of substance produced in the processing chamber 4 is negligible or zero, the flow rate of the gases discharged by the turbo molecular pump 29 is equal to the flow rate in the cases shown in FIGS. 2 and 3, and the effective discharge speed Seff achieved by the variable conductance valve 28 and the preset pressure in the processing chamber 4 are equal to those in the cases shown in FIGS. 2 and 3

In any of the examples shown in FIGS. 2 to 4 described above, the flow rate of the processing gases that flow into the processing chamber 4 per unit time (flow rate speed) does not change. Therefore, even in an etching process in which a step using the process gas a and a step using the process gas b are switched from one to the other during the process, the amount of change in the pressure in the processing chamber 4 that occurs in the gas switching operation during the process is reduced by setting an effective discharge speed Seff that allows the pressure in the processing chamber 4 to be maintained within a predetermined range in accordance with the overall flow rate of the processing gas that is the combination of the process gas a and the process gas b and setting the angles in the variable conductance valve 28 that correspond to the thus set effective discharge speed Seff before the start of the etching process.

As a result, a process start standby period from the timing at which a gas flow rate or composition is switched to another gas flow rate or composition to the timing at which the pressure in the processing chamber 4 reaches an intended value suitable for the switched gas process condition is shortened, whereby a decrease in throughput in the process is reduced. Further, a situation is avoided in which, when the process is initiated without the standby period to reach the suitable pressure condition, the result of the process undesirably deviates from a desired result and the yield in the process therefore lowers.

In the present embodiment, each of the step using the process gas a and the step using the process gas b takes a period shorter than or equal to several seconds. In these steps, adjustment using the variable conductance valve 28 is not undesirably responsive enough because the adjustment typically requires several tens of seconds until the pressure settles. The process gas introduction configuration in the embodiment described above, however, allows the pressure in the processing chamber to have an intended value in a short period, whereby the process gas switching can be performed at high speed for high-precision etching of the film under processing on the wafer 11.

In the present embodiment, a process gas introduced through a portion below the placement surface of the wafer placement electrode 10 without passing through the shower plate 2 is a non-excited, raw-state gas, most of which is discharged from a portion below the wafer placement electrode 10 through the vacuum discharge port 5. Therefore, the process gas supplied to a lower portion of the processing chamber 4 described above can be made not to substantially contribute to the etching of the wafer 11.

Further, each of the process gas a and the process gas b may be a single gas or a composite gas that is a mixture of a plurality of kinds of substances, and substances contained in one of the gases may be contained in the other. In FIGS. 3 and 4 described above, the process gas a and the process gas b introduced into the processing chamber 4 through the shower plate 2 and used in the etching process may be composite gases that are mixtures of the same substances but the composition or the flow rate thereof differ from each other.

In the example described above, in a plurality of steps in which gas conditions including the flow rate and the composition are switched, a gas having an adjusted composition and flow rate is supplied through the opening 31 in each of the steps such that the flow rates and the compositions of the gases discharged through the vacuum discharge port 5 become the same or so similar to each other that they are approximately the same. Further, it is not limited to the two gas supply lines described in the embodiment, but a plurality of lines greater than or equal to two lines may also be employed.

In contrast to the related art disclosed in JP-A-2008-41723, in which an adjustment gas for preventing a change in the pressure in a processing chamber is introduced into a discharge line and supplied into the processing chamber through a discharge opening of the processing chamber, in the plasma processing apparatus according to the present embodiment in which the composition of a gas used to process the wafer 11 is switched to another composition during the process and the switching operation is repeated, there is no requirement of prohibition of the activation of an adjuster disposed in a position on the discharge line and adjusting the flow rate of a gas discharged through the discharge port (such as a component corresponding to the variable conductance valve 28 in the embodiment described above), but the plasma processing apparatus according to the present embodiment allows the pressure in the processing chamber 4 to be adjusted by activating the variable conductance valve 28 even during the processing of the wafer 11.

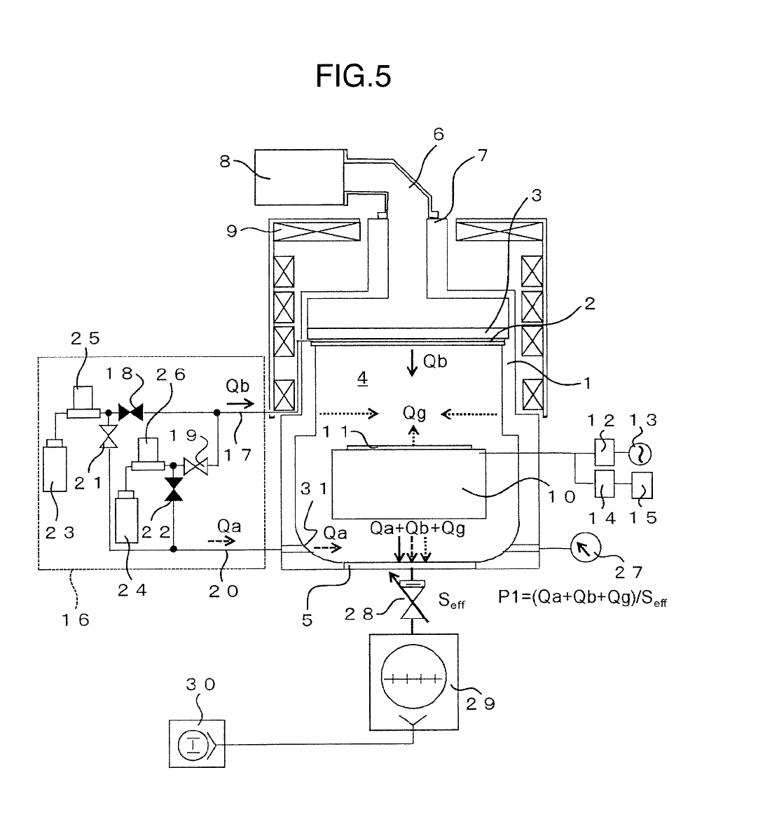

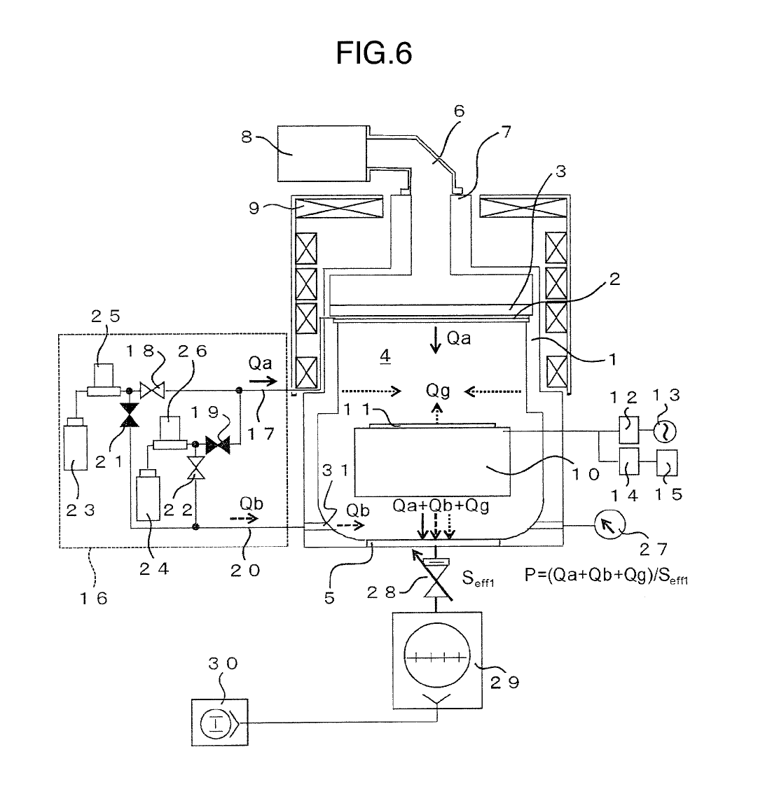

The present embodiment, in which the configuration described above is provided, can prevent the pressure in the processing chamber 4 from changing due to a reaction product produced during the process and the flow rate of the gases that flow out through the vacuum discharge port 5 from changing. This advantageous effect will be described with reference FIGS. 5 and 6.

FIGS. 5 and 6 are longitudinal sectional views schematically showing states in which a reaction product is formed in the plasma processing apparatus according to the embodiment shown in FIG. 1 during a process carried out by supplying process gases different from each other through the first and second gas supply paths. FIG. 5 shows a case where the process gas b is supplied to the processing chamber 4 through the first gas supply path 17 via the shower plate 2 and the process gas a is supplied to a lower portion of the processing chamber 4 through the second gas supply path 20 via the opening 31 FIG. 6 shows a case where the process gas a is supplied to the processing chamber 4 through the first gas supply path 17 via the shower plate 2 and the process gas b is supplied to the lower portion of the processing chamber 4 through the second gas supply path 20 via the opening 31.

As shown in FIG. 5, a reaction product is formed in the processing chamber 4 by the interaction among the plasma formed in the processing chamber 4, the wafer 11, and a member that forms the inner surface of the processing chamber 4 during the processing of the wafer 11. The reaction product is typically formed in a reaction in which the materials of the wafer 11 and the member that forms the inner wall surface of the processing chamber 4, which come into contact with the plasma, physically or chemically react with the particles in the plasma during the formation of the plasma.

Therefore, during the process in which such a reaction product is formed, it is believed that a reaction product produced by an amount Qg per unit time is introduced into the inner space of the processing chamber 4 (through introduction holes in the inner wall surface that is not shown and the surface of wafer 11) as well as the process gas a and the process gas b flowing at the flow rate Qa+Qb per unit time. In view of the fact described above, during the processing of the wafer 11 in which process steps carried out under conditions using the different process gases flowing by the amounts Qa and Qb are switched from one to the other, to achieve a pressure in the processing chamber 4 suitable for the conditions in the process steps, the amount of gases discharged through the vacuum discharge port 5 needs to be adjusted in correspondence with the flow rates Qa and Qb of the process gases and the amount Qg of formed reaction product.

That is, the reaction product produced by the amount Qg is also discharged by the turbo molecular pump 29 and the dry pump 30 through the variable conductance valve 28. In the case shown in FIG. 6, when the discharge capacity determined by the revolution speed or action of each of the discharge pumps is fixed, and the positions of the flaps of the variable conductance valve 28 are adjusted to achieve the amount of discharge corresponding to the flow rate Qa+Qb shown in FIGS. 2 to 4, the gases in the processing chamber 4 are discharged at the effective discharge speed Seff corresponding to the positions. In this case, the amount of gases in the processing chamber 4, which is the amount of gases introduced into the processing chamber 4 increased by Qg, (Qa+Qb+Qg), is greater than the amounts in the cases shown in FIGS. 2 to 4, and the pressure in the processing chamber 4 becomes P1 (>P).

In the example shown in FIG. 6, to change the pressure in the processing chamber 4 detected from an output from the pressure gauge 27 to the intended value P, the angular positions of the flaps of the variable conductance valve 28 are so adjusted based on an instruction signal from the controller such that the effective discharge speed of the gases discharged through the vacuum discharge port 5 changes from Seff to Seff1. As shown in the embodiment in FIGS. 2 to 4, in the process of etching the wafer 11, the step carried out under the condition that the processing gas supplied through the shower plate 2 into the processing chamber 4 is the process gas a and the step carried out under the condition that the processing gas is the process gas b are periodically switched from one to the other at intervals of several seconds during the etching process, and the process gas supply path used in the etching process is switched between the first gas supply path 17 and the second gas supply path 20. However, the flow rate of the processing gases among the gases discharged through the vacuum discharge port 5 does not substantially change but remains at Qa+Qb.

In view of the fact described above, in the example shown in FIG. 6, the adjustment of the pressure in the processing chamber 4 made by an increase or decrease in the effective discharge speed achieved by opening or closing the variable conductance valve 28 may be made in correspondence with the discharge flow rate Qg of the reaction product. The present invention is not limited to the embodiment described above and encompasses a variety of variations. For example, the above embodiment has been described in detail in order to describe the present invention in a plain manner, and the present invention is not necessarily limited to the embodiment having all the described configurations.

1. A plasma processing apparatus comprising:
a vacuum container;
a processing chamber that is disposed in the vacuum container and that has an inner space in which a plasma is formed;
a sample stage that is disposed in the processing chamber and that has a placement surface on which a wafer to be processed by using the plasma is placed;
a discharge port disposed below the sample stage in the processing chamber;
a discharge pump disposed such that the discharge pump is connected to the discharge port; and
an adjuster that adjusts an amount of gas discharged through the discharge port,
wherein a first process step of supplying a first processing gas from above the placement surface into the processing chamber and supplying a second processing gas from below the placement surface into the processing chamber to process the wafer by using the first processing gas and a second process step of supplying the second processing gas from above the placement surface into the processing chamber and supplying the first processing gas from below the placement surface into the processing chamber to process the wafer by using the second processing gas are repeatedly switched over therebetween to process the wafer, and the adjuster adjusts a pressure in the processing chamber to have a predetermined value during the processing of the wafer.

2. The plasma processing apparatus according to claim 1,
wherein the first processing gas and the second processing gas have compositions different from each other.

3. The plasma processing apparatus according to claim 1,
wherein the processing is performed such that the first and second process steps are periodically repeated, and a sum of flow rates of the first and second processing gases supplied to the processing chamber is set identical between the first and second process steps.

4. The plasma processing apparatus according to claim 1,
wherein the discharge port is disposed directly below the sample stage and such that the discharge port and a lower surface of the sample stage sandwich a space in the processing chamber, and a supply port through which the first and second processing gases are supplied to a portion below the placement surface is disposed directly below the sample stage in a position facing the lower surface and the space in the processing chamber.

5. A plasma processing method comprising the steps of:
placing a wafer to be processed on a placement surface of a sample stage disposed in a processing chamber in a vacuum container;
forming a plasma in the processing chamber;
repeatedly switching over between a first process step of supplying a first processing gas from above the placement surface into the processing chamber and supplying a second processing gas from below the placement surface into the processing chamber to process the wafer by using the first processing gas and a second process step of supplying the second processing gas from above the placement surface into the processing chamber and supplying the first processing gas from below the placement surface into the processing chamber to process the wafer by using the second processing gas to process the wafer; and
adjusting an amount of gas discharged through a discharge port disposed below the sample stage in the processing chamber during the processing of the wafer to adjust a pressure in the processing chamber to a predetermined value.

6. The plasma processing method according to claim 5,
wherein the first processing gas and the second processing gas have compositions different from each other.

7. The plasma processing method according to claim 5,
wherein the processing is performed such that the first and second process steps are periodically repeated, and a sum of flow rates of the first and second processing gases supplied to the processing chamber is set identical between the first and second process steps.

8. The plasma processing method according to claim 5,
wherein the discharge port is disposed directly below the sample stage and such that the discharge port and a lower surface of the sample stage sandwich a space in the processing chamber, and a supply port through which the first and second processing gases are supplied to a portion below the placement surface is disposed directly below the sample stage in a position facing the lower surface and the space in the processing chamber.
